(19) United States
(12) Patent Application Publication
(10) Pub. No.: US 2025/0023328 A1
(43) Pub. Date: Jan. 16, 2025

(54) Tunable Laser with an External Cavity

(71) Applicant: Stichting IMEC Nederland, Eindhoven (NL)

(72) Inventor: Ruud Oldenbeuving, Eindhoven (NL)

(21) Appl. No.: 18/770,130

(22) Filed: Jul. 11, 2024

(30) Foreign Application Priority Data
Jul. 13, 2023 (EP) 23185173.4

(51) Int. Cl. H01S 5/14; H01S 3/10; H01S 5/10

(52) U.S. Cl. CPC H01S 5/14; H01S 3/10053; H01S 5/1021

(57) ABSTRACT

Examples include a tunable laser, in particular, an external cavity type laser. Examples also include a method of operating the tunable laser. The tunable laser is designed for fast and repeatable wavelength tuning over a wide wavelength range. The tunable laser includes a cavity and a gain medium arranged in the cavity. The gain medium is configured to generate light by stimulated emission and to emit the light into the cavity. The tunable laser also includes a laser output configured to output a portion of the light in the cavity as a laser beam. The cavity includes a first resonator and a second resonator that are optically coupled to each other. A resonance frequency of the first resonator is tunable. A free spectral range (FSR) of the second resonator is an integer multiple of an FSR of the cavity.

### CROSS-REFERENCE TO RELATED APPLICATIONS

The present application is a non-provisional patent application claiming priority to European patent application no. 23185173.4, filed on Jul. 13, 2023, the contents of which are hereby incorporated by reference.

### FIELD OF THE DISCLOSURE

The present disclosure relates to a tunable laser, in particular, an external cavity type laser. The disclosure also relates to a method of operating the tunable laser. The tunable laser of this disclosure is designed for fast and repeatable wavelength tuning over a wide wavelength range.

### BACKGROUND

In integrated photonics, to design a tunable laser, it becomes increasingly important to integrate a suitable light source, for instance a laser diode, into a photonic integrated circuit (PIC). Tuning the spectral properties, such as wavelength, wavelength agility, spectral linewidth, coherence length, relative intensity noise, etc., of the laser, can be done via the proper design and fabrication of an additional external cavity in the PIC.

An example of such an external cavity comprises a set of tunable resonators, for instance, a set of two or more coupled ring resonators of slightly different circumferences. The external cavity with these tunable ring resonators can be coupled to, for example, a linear resonator or cavity of the light source, for example the laser diode, which contains a gain medium.

The external cavity allows making use of the Vernier effect, which can effectively increase the tunability of the laser, while decreasing the linewidth and further enhancing the spectral purity.

However, there is still a need to improve such integrated external cavity lasers and, in particular, to find new designs for external cavities.

### SUMMARY

In the above-described type of external cavity laser, the wavelength tuning is typically done via a relatively slow mechanism, such as phase tuning of the various resonators with phase shifters, for instance, heaters. By phase tuning the resonators, predefined laser wavelengths can be addressed.

For example, by tuning the phase of a first ring resonator of the external cavity, so as to first address lower wavelengths before moving to higher wavelengths, the resonant modes of a second (not tuned, i.e., stationary) ring resonator can be addressed as well. However, for each wavelength, the phase of the linear resonator needs to be tuned as well, to ensure that the wavelength fits inside the entire cavity of the laser and thus to avoid a power loss. This means that the speed of the phase shifter for the linear resonator is a bottleneck in terms of the overall tuning speed of the laser. As a consequence, the aforementioned switching scheme, from the lowest to the highest wavelength of the first ring resonator, cannot be practically addressed.

In view of this, the present disclosure aims to provide an improved tunable laser with an external cavity. A potential benefit is, in particular, to provide a tunable laser, which can be tuned fast without experiencing significant power loss. A potential benefit is to circumvent the above-described bottleneck of needing to tune a phase shifter of a linear resonator, when implementing the scheme of tuning a first resonator while keeping a second resonator stationary.

A first aspect of this disclosure provides a tunable laser comprising: a cavity; a gain medium arranged in a region of the cavity, the gain medium being configured to generate light by stimulated emission and to emit the light into the cavity; and a laser output configured to output a portion of the light in the cavity as a laser beam; wherein the cavity includes a first resonator and a second resonator that are optically coupled to each other, wherein a resonance frequency of the first resonator is tunable; and wherein a free spectral range (FSR) of the second resonator is an integer multiple of a FSR of the cavity.

Because the FSR of the second resonator is matched in the above-described way to the FSR of the entire cavity of the tunable laser, the first resonator can be tuned while the second resonator is kept stationary, and no power loss occurs even without operating any other phase shifter. Thus, only the first resonator needs to be tunable in the laser of the first aspect. The tunable laser can moreover be tuned fast without experiencing the power loss. The design of the second resonator and the cavity of the laser allows circumventing the above-described bottleneck of a phase shifter of a linear resonator that has to be tuned, when tuning the first resonator and keeping the second resonator stationary.

The gain medium may, for example, be based on semiconductor material of a semiconductor laser diode. The laser diode may comprise the region of the cavity where the gain medium is located. The resonators may form an external cavity coupled to the laser diode. The laser diode and the external cavity may be integrated on a PIC.

In an implementation of the laser, the cavity includes a linear resonator, the gain medium is arranged in a region of the linear resonator, and the linear resonator is optically coupled to the first and the second resonator.

The gain medium and the linear resonator may, for instance, form the laser diode. The laser diode may be coupled to the external cavity including the first and the second resonator. The resulting tunable laser may be a hybrid external cavity laser.

In an implementation of the laser, the linear resonator is optically coupled to the first and the second resonator by an optical splitter; and the optical splitter is configured to allow light to couple from the linear resonator into the first and the second resonator and to allow light to couple from the first and the second resonator into the linear resonator.

In an implementation of the laser, the optical splitter is further optically coupled to the laser output.

In an implementation of the laser, a resonance frequency of the linear resonator is tunable.

That is, the linear resonator can be tunable in the laser of the first aspect, but this is not a requirement. While the tunability of the linear resonator may enhance the tunability of the laser as a whole, it is not required for the wavelength tuning scheme that is described above. The tunability of the linear resonator may be useful for defining the tunable wavelength range of the laser, for instance, by setting a starting point.

In an implementation of the laser, a resonance frequency of the second resonator is tunable.

That is, the second resonator can be tunable in the laser of the first aspect, but this is not a requirement. While the tunability of the second resonator may enhance the tunability of the laser as a whole, it is not required for the wavelength tuning scheme described above, in particular, since the second resonator is anyhow kept stationary in this scheme.

In an implementation of the laser, the laser further comprises one or more phase shifters; wherein a first phase shifter of the one or more phase shifters is configured to tune the resonance frequency of the first resonator.

In an implementation of the laser, a second phase shifter of the phase shifters is configured to tune the resonance frequency of the second resonator; and/or a third phase shifter of the phase shifters is configured to tune the resonance frequency of the linear resonator.

In an implementation of the laser, at least one of the resonance frequency of the second resonator and the resonance frequency of the linear resonator is not tunable.

In an implementation of the laser, the first resonator is a first ring resonator and/or the second resonator is a second ring resonator.

The first and the second resonator can alternatively be Mach-Zehnder-Interferometers, or Fabry-Perot-Interferometers, or similar kinds of resonators.

In an implementation of the laser, the first ring resonator has a different circumference than the second ring resonator.

This leads to different resonance frequencies of the ring resonators and thus enhances the tunability of the laser.

In an implementation of the laser, the cavity includes one or more additional resonators, which are optically coupled to each other and to the first and the second resonator.

In an implementation of the laser, a resonance frequency of at least one of the additional resonators is tunable.

The one or more additional resonators contribute to the entire cavity, and thus the FSR of the entire cavity.

A second aspect of this disclosure provides a method for operating a tunable laser system of the first aspect or any of its implementations, wherein the method comprises: tuning the resonance frequency of the first resonator; and keeping the resonance frequency of the second resonator fixed, while tuning the resonance frequency of the first resonator.

In an implementation of the method, tuning the resonance frequency of the first resonator produces a plurality of peaks in power of the laser beam output by the laser output, wherein the power of each peak is equal.

The method of the second aspect can achieve the same advantages as the tunable laser of the first aspect, and may be extended by respective implementations as described above for the tunable laser of the first aspect. The method allows tuning the laser without power loss and with increased speed compared to a similar laser, which does not have the FSR of the second resonator matched to the FSR of the cavity.

In summary of the above aspects and implementations, this disclosure provides a fast-tunable external cavity laser with a set of resonators, for instance ring resonators, in an external cavity. The preferred tuning scheme works by tuning a first resonator of the set of resonators from a lowest to highest wavelength, while keeping a second resonator (and optionally one or more additional resonators) of the set of resonators stationary. The tunable laser is based on a specific cavity design, according to which the FSRs of the second resonator and the entire cavity of the laser are matched as described above, to enable the fast tunability.

### BRIEF DESCRIPTION OF THE FIGURES

The above, as well as additional, features will be better understood through the following illustrative and non-limiting detailed description of example embodiments, with reference to the appended drawings.

FIG. 1 shows a tunable laser, according to an example.

FIG. 2 shows a tunable laser with two ring resonators and a linear resonator,

according to an example.

FIG. 3 shows a tunable laser with two ring resonators, a linear resonator, and three phase shifters, according to an example.

FIG. 4(a) shows a filter response when tuning a first ring resonator, according to an example.

FIG. 4(b) shows a filter response when tuning a second ring resonator, according to an example.

FIG. 4(c) shows filter responses when tuning a first ring resonator, a second ring resonator, and a superposition of those responses, according to an example.

FIG. 4(d) shows a superposition of the filter response when tuning a first ring resonator and the filter response when tuning a second ring resonator, according to an example.

FIG. 5(a) shows a filter response of a first tuning setting of two or more ring resonators of a tunable laser, according to an example.

FIG. 5(b) shows a filter response of a second tuning setting of two or more ring resonators of a tunable laser, according to an example.

FIG. 5(c) shows a filter response of a third tuning setting of two or more ring resonators of a tunable laser, according to an example.

FIG. 5(d) shows a filter response of a fourth tuning setting of two or more ring resonators of a tunable laser, according to an example.

FIG. 6(a) shows a laser out power when tuning the first resonator and keeping the second resonator of a conventional laser stationary, according to an example.

FIG. 6(b) shows a laser out power when tuning the first resonator and keeping the second resonator of a laser of this disclosure stationary, according to an example.

FIG. 7 shows a method of operating a tunable laser, according to an example.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

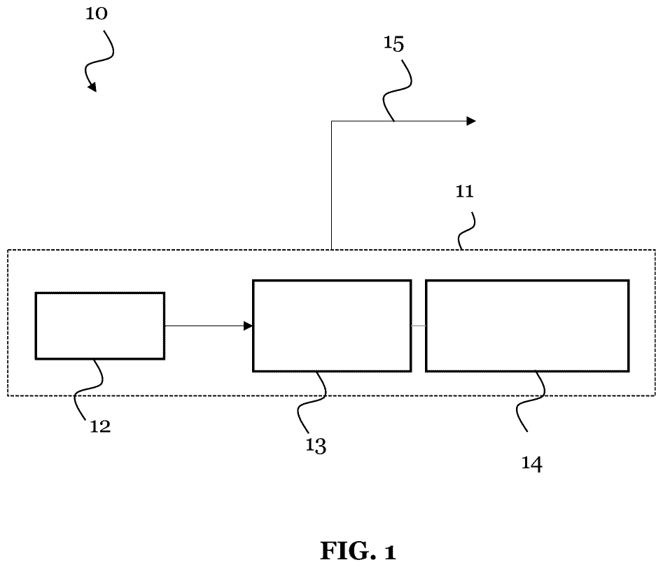

FIG. 1 shows a tunable laser 10 according to this disclosure. The tunable laser 10 comprises a cavity 11 that comprises at least a first resonator 13 and a second resonator 14. The tunable laser 10 may be referred to as an external cavity tunable laser, wherein the cavity 11 includes one or more external components—in this case the first resonator 13 and the second resonator 14 that may form the external cavity—to enable a greater control over the spectral properties of a laser beam that is generated by the tunable laser 10.

The laser 10 comprises a gain medium 12, which is arranged in a region of the cavity 11. The gain medium 12 is configured to generate light by stimulated emission, and to emit the generated light into the cavity 11. The gain medium 12 might not be distributed throughout the entire cavity 11. For instance, the gain medium 12 might not be arranged in the external cavity, which provides an optical path for the emitted light that extends beyond the immediate region that houses the gain medium 12. The region housing the gain medium 12 may be a linear resonator, for instance an internal cavity of a laser diode, which may be coupled to the first resonator 13 and the second resonator 14 being part of the external cavity.

The laser 10 also comprises a laser output 15, which is configured to output a portion of the light in the cavity 11 as a laser beam. The light in the cavity 11 may be amplified by passing through the gain medium 12 one or multiple times and by constructive interference in the cavity 11, particularly, in the first resonator 13 and the second resonator 14.

The first resonator 13 and the second resonator 14 are optically coupled to each other, and a resonance frequency of at least the first resonator 13 is tunable. A resonance frequency of the second resonator 14 may also be tunable, but it may also be not tunable. Due to the tunability of at least the first resonator 13, which allows changing the properties of the cavity 11, the wavelength of the laser beam provided at the laser output 15 can be adjusted or tuned.

The potential benefit of this disclosure lies in the design of the second resonator 14 and the cavity 11, in particular, matching the second resonator 14 specifically to the cavity 11 as follows. An FSR of the second resonator 14 is an integer multiple of an FSR of the cavity 11 (i.e., the entire cavity 11 including the second resonator 14). Mathematically this can be described by the following Equation (1):

Δvᵣ=n·Δvₜₒₜ (1)

In this equation, Δvᵣ is the FSR of the second resonator 14 (in Hz), Δvₜₒₜ is the FSR of the entire laser cavity 11 (in Hz), and n is a positive integer number larger than zero. Notably, the FSR may denote the distance between adjacent resonance peaks, as explained below.

The potential benefits of this design of the laser 10, especially of the matched FSRs of the second resonator 14 and the cavity 11, are described in more detail in the following. Thereby, an example of the tunable laser 10 with specifically two ring resonators as the first resonator 13 and the second resonator 14 is used. However, the disclosure is not limited to the use of such ring resonators. The first resonator 13 and the second resonator 14 could, respectively, be a Mach-Zehnder-Interferometer, or a Fabry-Perot-Interferometer, or the like.

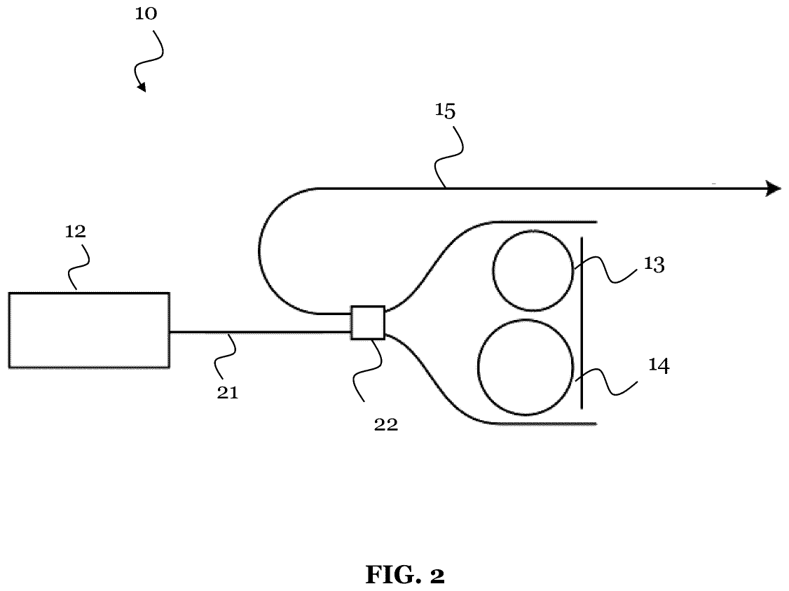

FIG. 2 shows a tunable laser 10 with at least two ring resonators, which builds on the tunable laser 10 shown in FIG. 1. The tunable laser 10 shown in FIG. 2 has a first ring resonator 13 and a second ring resonator 14 that are part of an external cavity.

FIG. 2 shows that the layout of the laser 10 comprises a gain region, in which the gain medium 12 is contained (left-hand side), and shows waveguides defining the rest of the cavity 11 (on the right-hand side). The cavity 11 may include a linear resonator 21, for instance, of a laser diode, and the gain medium 12 may be arranged in a region of this linear resonator 21. The linear resonator 21 may be an internal cavity, for instance, of the laser diode. The linear resonator 21 is optically coupled to the external cavity comprising at least the first resonator 13 and the second ring resonator 14. For instance, the linear resonator 21 may be coupled to the first ring resonator 13 and the second ring resonator 14 by an optical splitter 22, which is configured to allow light to couple from the linear resonator 21 into the first ring resonator 13 and the second ring resonator 14, respectively, and also to allow light to couple from the first ring resonator 13 and the second ring resonator 14, respectively, into the linear resonator 21.

As shown by the schematic illustration of the tunable laser 10 in FIG. 2, the first ring resonator 13 and the second ring resonator 14 may have different circumferences. The laser output 15, which is configured to output the laser beam, is also shown, and is coupled to the optical splitter 22.

Notably, the potential benefit of this disclosure is not limited to this exact scheme, even in case of using the first ring resonator 13 and the second ring resonator 14. For instance, the cavity 11 could include one or more additional (e.g., ring) resonators, which may be optically coupled to each other and to the first resonator 13 and the second resonator 14. In an example, a resonance frequency of at least one of these additional resonators may be tunable.

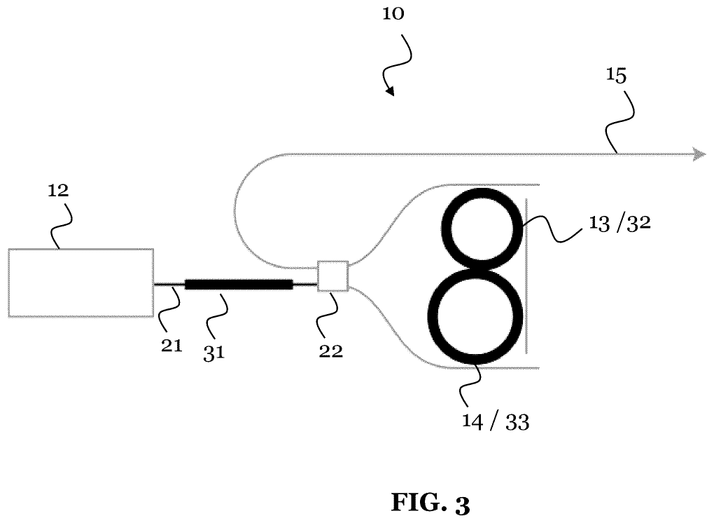

In the tunable laser 10 shown in FIG. 2, the wavelength tuning may be caused by tuning at least the first ring resonator 13, which may be implemented with a phase shifter. For example, as shown in FIG. 3, the tunable laser 10 may comprise one or more phase shifters 31, 32, 33. A first phase shifter 32 may be arranged and configured to tune the resonance frequency of the first resonator 13. The first phase shifter 32 may be the only phase shifter of the tunable laser 10, i.e., the laser 10 may comprise only a single phase shifter 32 to tune the first resonator 13. In this case, the resonance frequency of the second resonator 14 and the resonance frequency of a potential linear resonator 21 are not tunable.

However, as illustrated in FIG. 3, the laser 10 may also comprise a second phase shifter 33, which may be arranged and configured to tune the resonance frequency of the second resonator 14. The laser 10 may also comprise a third phase shifter 31, which may be arranged and configured to tune the resonance frequency of the linear resonator 21. In other words, at least one of the resonance frequency of the second resonator 14 and the resonance frequency of the linear resonator 21 is tunable as well. The (typical) locations of the phase shifter 31, the phase shifter 32, and the phase shifter 33 are indicated in FIG. 3 with the thicker black lines.

Each of the phase shifter 31, the phase shifter 32, and the phase shifter 33 may be or comprise a heater, i.e., the tuning of the various resonator(s) of the laser 10 may be done with heaters. Other phase shifters and phase shifting mechanisms may be used as well, for instance, using stress to change a refractive index of the resonators or using liquid crystal technology. By phase tuning at least the first ring resonators 13, predefined wavelengths of the laser 10 can be addressed.

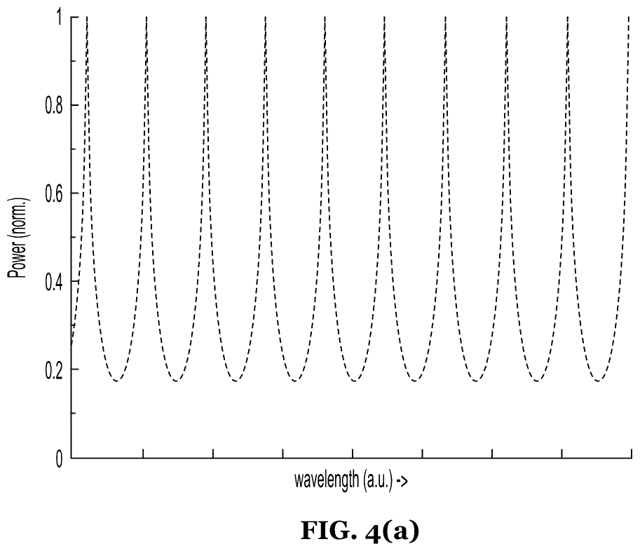

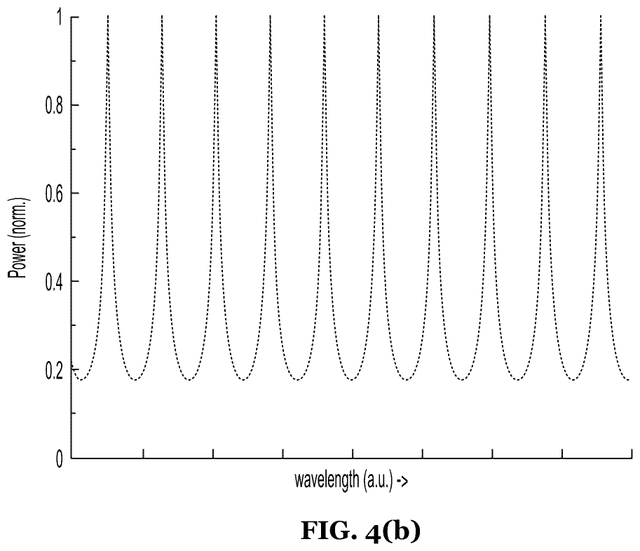

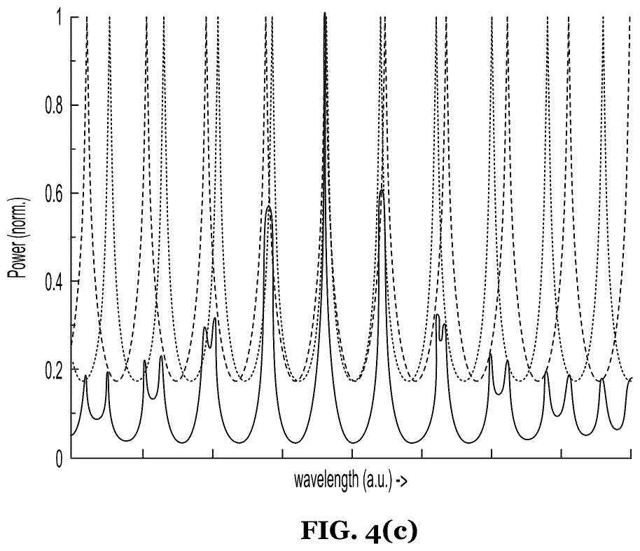

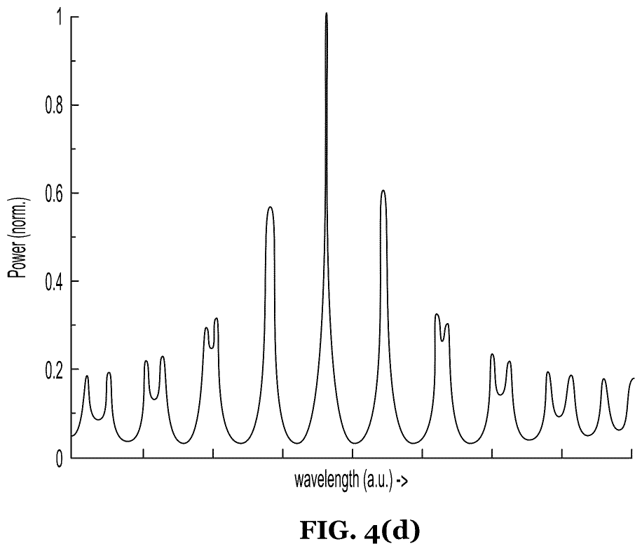

FIG. 4(a) shows a filter response (power vs. wavelength) of a first ring resonator 13 and FIG. 4(b) shows a filter response of the second ring resonator 14. Combining these filter responses gives a frequency response as shown in FIG. 4(d), while all three filter responses are overlaid in FIG. 4(c).

An important parameter of the spectral response of a resonator is the so-called the FSR. The FSR is defined as the distance between adjacent resonant frequencies of the resonator. FIG. 4(a), for example, shows that the FSR of the first ring resonator 13 is from peak-to-peak. Note that the FSR of the first ring resonator 13 and the second ring resonator 14 are slightly different as shown in FIG. 4(a) and FIG. 4(b). When the first ring resonator 13 and the second ring resonator 14 are combined in series (as is the case in FIG. 2 and FIG. 3), the combined filter response is that of the thick line in FIG. 4(c) and FIG. 4(d). In FIG. 4(c) the large dotted line represents the filter response of the second ring resonator 14, and the small dotted line represents the filter response of the first ring resonator 13.

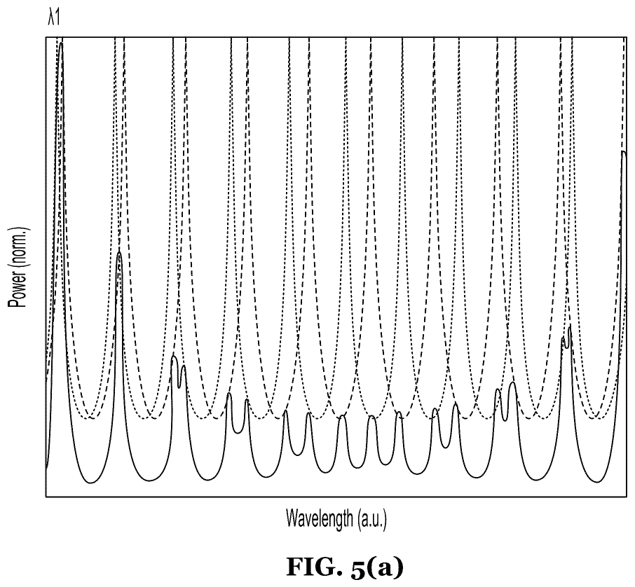

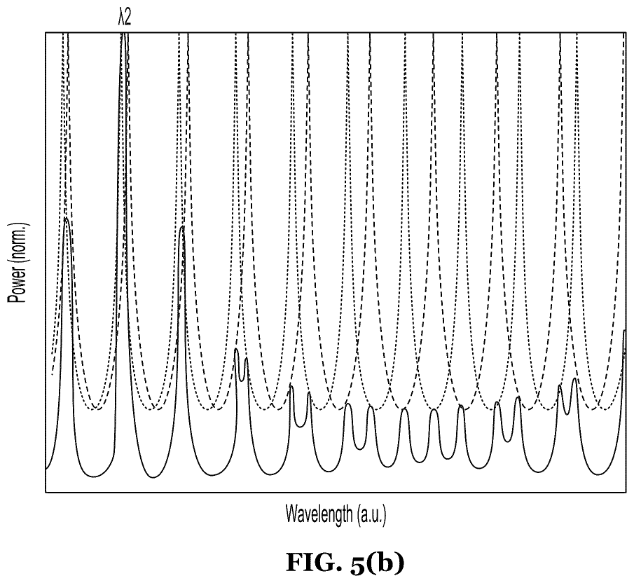

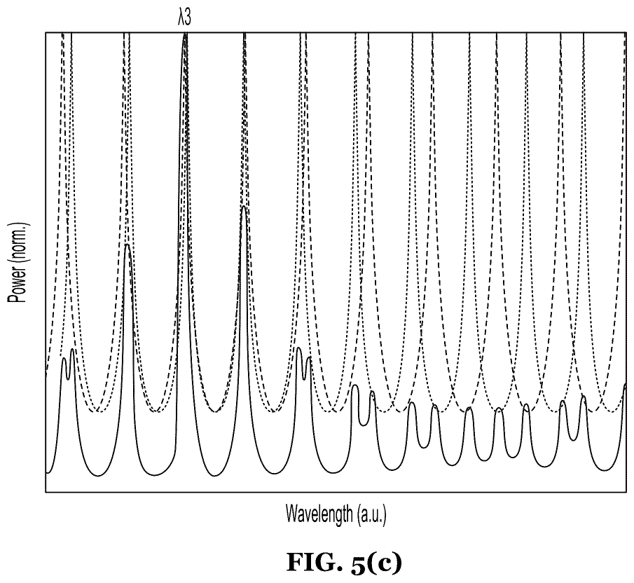

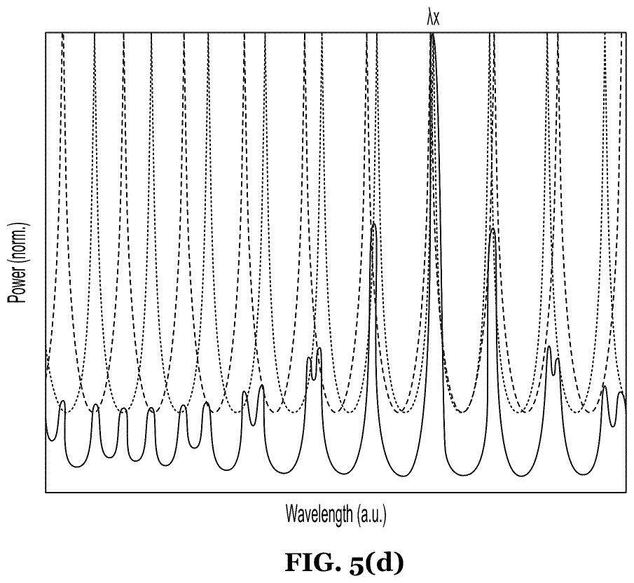

The tunable laser 10 of this disclosure may be operated according to a tuning scheme, wherein the first ring resonator 13 is tuned over 2 pi, while the second ring resonator 14 is kept stationary (i.e., is not tuned, regardless of whether it is tunable or not). While tuning in this way, the combined filter response moves over the entire spectrum, thus addressing all peaks of the second ring resonator 14. A few of the resulting spectra corresponding to different settings during the tuning are depicted in FIG. 5(a), FIG. 5(b), FIG. 5(c), and FIG. 5(d). The small-dotted line moves towards the right-hand-side of the graphs when looking first at λ1 in FIG. 5(a), then at λ2 in FIG. 5(b), then at λ3 in FIG. 5(c), and finally at Aλx in FIG. 5(d). The sequence λ1, λ2, λ3 is followed equally until reaching λx. A 2 pi phase shift will have occurred when the frequency response looks like λ1 again.

When the spectrum shown in FIGS. 4(a)-(d) and FIGS. 5(a)-(d) is fed back into the gain region, i.e., to the gain medium 12 of the laser 10 shown in FIG. 2, a laser beam is emitted when there is enough coherent buildup of light inside the cavity 11. This is the case when an integer number of waves fit inside the cavity 11, causing constructive interference. If the wavelength becomes slightly larger, the constructive interference may still present inside the cavity 11, but not as pronounced, which leads to a lower laser output. When the wavelength is sufficiently larger, destructive interference may even be dominant and (almost) no coherent light will be emitted from the laser 10 in this case. This can be measured by a significant decrease in the laser output power, but also when looking at the spectrum of the output of the laser 10 (a loss of the laser-line).

If in the tunable laser 10, the FSR of the second ring resonator 14 would not be an integer multiple of the FSR of the cavity 11, then the above wavelength tuning scheme would have to be done as follows. When tuning the first resonator 13 from the lowest to the highest wavelength, to address each wavelength of the second resonator 14, the wavelengths would not necessarily all fit into the cavity 11. Thus, the phase shifter of the linear resonator 21 would have to be operated in addition to tune the linear resonator 21 such that the wavelength fits. That is, the wavelength tuning scheme would be performed setting-to-setting. When using a typical type of phase shifter, like a heater, this would result in a rather slow tuning mechanism. Because the tuning is not instantaneous, a certain time would be needed each time until a steady state is reached. In other words, the wavelength tuning would be slow and nearly impracticable.

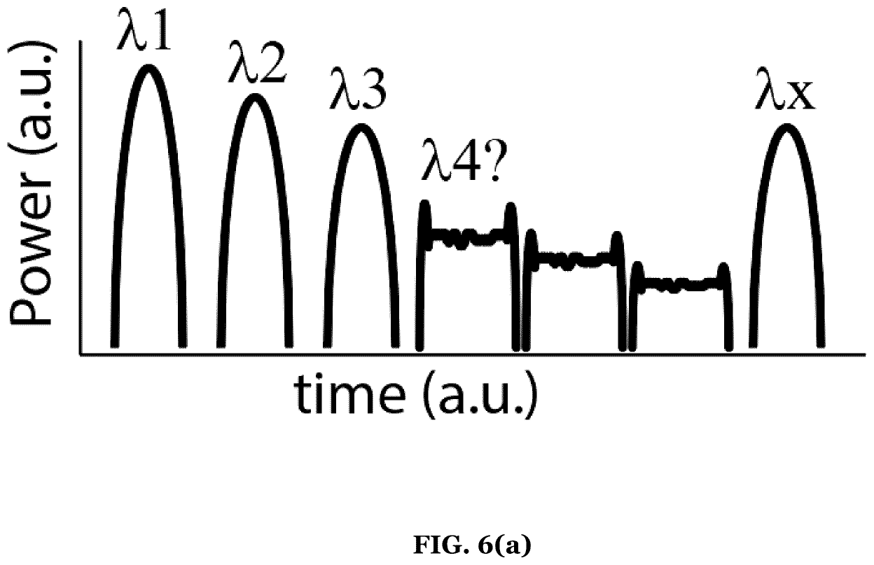

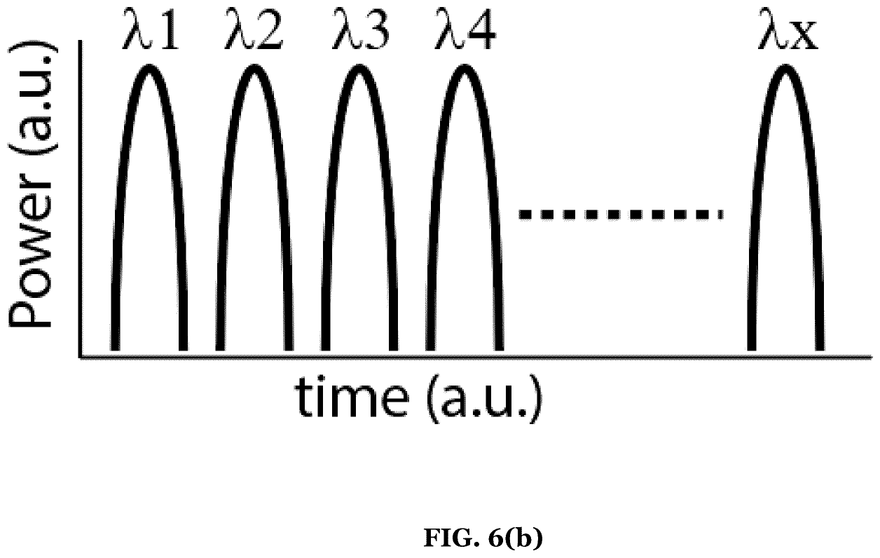

However, not tuning the linear resonator 21 would result in power loss. FIG. 6(a) and FIG. 6(b) compare in this respect a laser 10 of this disclosure and a conventional laser. The laser 10 is shown in FIG. 6(b), and has the FSR of the second ring resonator 14 designed to be an integer multiple of the FSR of the cavity 11. The conventional laser is shown in FIG. 6(a) and is mostly similar to the laser 10, but does not have the FSR of the second ring resonator 14 matched to the FSR of the cavity 11. In both cases, the switching from the lowest wavelength λ1 to a higher wavelength λx is measured by monitoring the output power of the laser vs. the time (during which the tuning mechanism is performed). In both cases only the first resonator 13 is tuned, and no other phase shifter is operated.

In FIG. 6(a), λ1 fits an integer number times in the laser cavity 11, causing constructive interference and coherent laser output. However, λ2 and λ3 already show a lower output power and where λ4 should be, a non-coherent output with low power is seen. When the wavelength of the external cavity 11 is tuned even further, at a certain point the next integer number of wavelengths will fit inside the cavity 11 again, causing a sudden increase in output power and coherence (depicted as λx).

In FIG. 6(b), due to the design of the laser 10 of this disclosure, such a drop is not observed. Notably, in the exemplary laser of FIG. 6(a), the drop in output power and decrease in coherence could be solved by tuning the linear resonator 21. In this case, the output power over time may even look like in FIG. 6(b). However, because the third phase shifter 31 is a physical phase shifter, which requires a larger-than 2 pi phase shift to address the different wavelengths imposed by a 2 pi phase shift of the first ring resonator 13, the speed of wavelength tuning would be limited by the tuning speed of the third phase shifter 31. A fast tuning over the entire spectrum is generally not possible.

The laser 10 of this disclosure does not require such tuning of the linear resonator 21. In fact, it does thus not require a tunable linear resonator 21 at all. To tune the laser 10 with high speed the preferred measurement is shown in FIG. 6(b), where all wavelengths are addressed at equal power over the entire tuning range. The laser 10 of this disclosure can avoid the previously described bottleneck of continuously having to tune the linear resonator 21 to allow for equal laser power.

The relevance of the FSR can be explained as follows. To make sure that the required constructive interference occurs, an equal number of waves need to fit inside the cavity 11. The wavelength difference between these wavelengths is the FSR of the cavity 11. All wavelengths that fit inside the cavity 11 (matching the wavelengths of the FSR of the cavity 11) are so-called cold cavity modes. For a ring resonator, like the second ring resonator 14, such cavity modes exist as well and have their own FSR. This FSR of the second ring resonator 14 is related to the circumference of the second ring resonator 14. The cold cavity modes of a laser with a set of at least two ring resonators as external waveguide circuit have a smaller FSR than the ring resonators themselves. By matching a multitude of the cold cavity mode spacing with the FSR of the stationary second ring resonator 14, all modes of the stationary second ring resonator 14 that are addressed will be resonant for the entire laser. As already mentioned above, this FSR matching can be mathematically described by Equation (1).

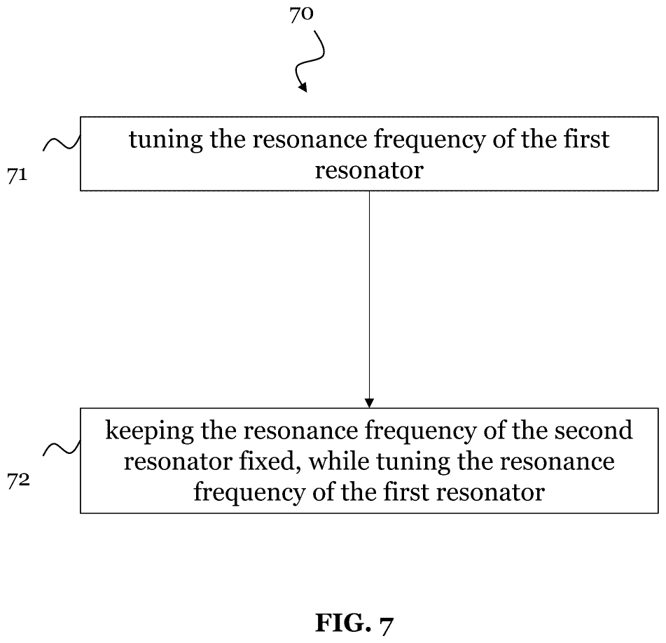

FIG. 7 shows a method 70 of operating the tunable laser 10, as shown in FIG. 1 or FIG. 2. The method 70 comprises tuning 71 the resonance frequency of the first resonator 13, while keeping 72 the resonance frequency of the second resonator 14 fixed. Due to the design of the laser 10 and particularly the matching of the FSR of the second ring resonator 14 with the FSR of the cavity 11, the tuning of the resonance frequency of the first resonator 13 produces a plurality of peaks in power of the laser beam output by the laser output 15, wherein the power of each peak is equal, as shown in FIG. 6(b).

In summary, by matching the second ring resonator 14 to the cavity 11 regarding their FSRs, all peaks of the second resonator 14 can be addressed by tuning the first resonator 13 without a drop in power. Therefore, tuning other parts of the cavity 11, like the linear resonator 21, can be omitted and the speed of the tuning can thus be significantly increased.

In the claims as well as in the description of this disclosure, the word “comprising” does not exclude other elements or steps and the indefinite article “a” or “an” does not exclude a plurality. A single element may fulfill the functions of several entities or items recited in the claims. The mere fact that certain measures are recited in the mutual different dependent claims does not indicate that a combination of these measures cannot be used in an advantageous implementation.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A tunable laser comprising:
a cavity that includes a first resonator and a second resonator that are optically coupled to each other, wherein a resonance frequency of the first resonator is tunable, wherein a free spectral range (FSR) of the second resonator is an integer multiple of an FSR of the cavity;
a gain medium arranged in the cavity, the gain medium being configured to generate light by stimulated emission and to emit the light into the cavity; and
a laser output configured to output a portion of the light in the cavity as a laser beam.

2. The tunable laser of claim 1, wherein the cavity includes a linear resonator, the gain medium is arranged in the linear resonator, and the linear resonator is optically coupled to the first resonator and the second resonator.

3. The tunable laser of claim 2, wherein a second resonance frequency of the linear resonator is tunable.

4. The tunable laser of claim 2, wherein a second resonance frequency of the linear resonator is not tunable.

5. The tunable laser of claim 1, further comprising:
an optical splitter; and
a linear resonator that is optically coupled to the first resonator and the second resonator by the optical splitter, wherein the optical splitter is configured to allow light to couple from the linear resonator into the first resonator and the second resonator.

6. The tunable laser of claim 5, wherein the optical splitter is configured to allow light to couple from the first resonator and the second resonator into the linear resonator.

7. The tunable laser of claim 5, wherein the optical splitter is further optically coupled to the laser output.

8. The tunable laser of claim 5, wherein a second resonance frequency of the linear resonator is tunable.

9. The tunable laser of claim 1, wherein a resonance frequency of the second resonator is tunable.

10. The tunable laser of claim 1, further comprising a first phase shifter that is configured to tune the resonance frequency of the first resonator.

11. The tunable laser of claim 10, further comprising:
a second phase shifter that is configured to tune a second resonance frequency of the second resonator.

12. The tunable laser of claim 11, further comprising:
a linear resonator; and
a third phase shifter that is configured to tune a third resonance frequency of the linear resonator.

13. The tunable laser of claim 1, wherein the resonance frequency of the second resonator is not tunable.

14. The tunable laser of claim 1, wherein the first resonator is a first ring resonator.

15. The tunable laser of claim 14, wherein the second resonator is a second ring resonator.

16. The tunable laser of claim 15, wherein the first ring resonator has a different circumference than the second ring resonator.

17. The tunable laser of claim 1, wherein the cavity includes one or more additional resonators, which are optically coupled to each other and to the first resonator and the second resonator.

18. The tunable laser of claim 17, wherein a resonance frequency of at least one of the additional resonators is tunable.

19. A method for operating the tunable laser of claim 1, wherein the method comprises:
tuning the resonance frequency of the first resonator, and
keeping the resonance frequency of the second resonator fixed, while tuning the resonance frequency of the first resonator.

20. The method of claim 19, wherein tuning the resonance frequency of the first resonator produces a plurality of peaks in power of the laser beam output by the laser output, wherein the power of each peak is equal.
